(19) United States
(12) Patent Application Publication
(10) Pub. No.: US 2024/0377767 A1
(43) Pub. Date: Nov. 14, 2024

(54) IMPRINT APPARATUS, IMPRINT METHOD, AND ARTICLE MANUFACTURING METHOD

(71) Applicant: CANON KABUSHIKI KAISHA, Tokyo (JP)

(72) Inventor: MIZUKI ISHIMOTO, Tochigi (JP)

(21) Appl. No.: 18/644,832

(22) Filed: Apr. 24, 2024

(30) Foreign Application Priority Data
May 11, 2023 (JP) 2023-078614

(51) Int. Cl. G03F 9/00; G03F 7/00

(52) U.S. Cl. CPC G03F 9/7042; G03F 7/0002; G03F 9/7046; G03F 9/7049; G03F 9/7092; G03F 9/7096

(57) ABSTRACT

To reduce the occurrence of rework in the imprint process, an imprint apparatus that executes an imprint process of forming a pattern to an imprint material on a substrate using a mold includes an observation unit configured to observe a plurality of marks formed on the mold, and a control unit configured to select the marks to be used in the imprint process based on positions of the marks on the mold, cause the observation unit to observe the selected marks before the imprint process is executed, and determine whether or not the imprint process is executable, based on an observation result.

### BACKGROUND OF THE INVENTION

### Field of the Invention

The present invention relates to an imprint apparatus, an imprint method, and an article manufacturing method.

### Description of the Related Art

An imprint apparatus that molds an imprint material on a substrate using a mold having a surface on which a pattern is formed has been attracting attention as one of pieces of lithography equipment for mass production of a semiconductor device or the like.

An imprint apparatus can form a protruding/recessed pattern made of an imprint material on a substrate by curing the imprint material in a state in which a mold and the imprint material on the substrate are brought into contact with each other and pulling out the mold from the cured imprint material. In the imprint apparatus, a die-by-die alignment method is generally used in alignment between the mold and the substrate.

In the die-by-die alignment method, marks provided on the mold and the substrate are superposed in a state in which the mold and the imprint material on the substrate are brought into contact with each other. The method involves measuring a relative positional deviation amount between the mold and the substrate from moire detected in a composite image and driving the mold and the substrate while correcting the deviation, thereby performing alignment with high accuracy.

However, in the alignment of the die-by-die alignment method that is performed during an imprint process, the problem that the alignment mark cannot be correctly detected may often occur. If foreign matter is stuck to the alignment mark or if a treated surface of the alignment mark has peeled off due to cleaning of the mold and the optical characteristics of a mark surface have changed, the alignment mark may not be correctly detected.

Even if a mark pattern of alignment marks which are actually used in the imprint process is different from a mark pattern of an alignment mark acquired from recipe information, the relative positional deviation amount may not be correctly detected.

The mark pattern stated herein is a pattern or a shape that forms an alignment mark, and a direction of the alignment mark. The mark pattern is registered in a recipe by a user before the imprint process, but may be different from an actual mark pattern due to erroneous registration of the user.

In the die-by-die alignment method, a plurality of shot regions are provided on one substrate, and repeated alignment and imprint processes are performed on the same substrate according to the number of shot regions.

If an abnormality occurs in the detection of the alignment marks during the imprint process, the alignment cannot be correctly performed, the imprint process cannot be continued and stopping due to an error occurs. If the error stop occurs in mass production, the alignment accuracy for the shots that have been stopped due to an error cannot be guaranteed, and thus the substrate must be reworked.

In the die-by-die alignment method, because alignment marks to be used can be changed for each shot, the alignment marks which are optimum for alignment can be selected for each shot.

On the other hand, if an abnormality occurs even at one place in the detection of the alignment mark during the imprint process, the substrate has to be reworked. If the substrate is to be reworked, the imprint material on the substrate needs to be removed immediately, and the substrate needs to be regenerated in a state before the imprint process, resulting in reduction in productivity.

In regard to the above-described problem, in Japanese Patent Laid-Open No. 2017-103297, before detection of an alignment mark is performed, a mark that cannot be used in detection of a relative positional deviation is selected as a prohibition mark by a user.

The selected prohibition mark is not used in alignment, so that the occurrence of an abnormality in the detection of the alignment mark is prevented. Furthermore, in Japanese Patent Laid-Open No. 2016-96269, if an abnormality occurs in detection of an alignment mark, a recovery process for detecting the alignment mark normally is executed, so that throughput is improved.

However, in Japanese Patent Laid Open No. 2017-103297, if there is a mistake in selection of a prohibition mark due to an erroneous operation of the user, an abnormality in the detection of the alignment mark cannot be prevented. In Japanese Patent Laid-Open No. 2016-96269, because the recovery process is executed after the mold and the substrate are brought into contact with each other, if the recovery fails, the substrate is to be reworked.

### SUMMARY OF THE INVENTION

According to an aspect of the present invention, an imprint apparatus that executes an imprint process of forming a pattern to an imprint material on a substrate using a mold includes at least one processor or circuit configured to function as: an observation unit configured to observe a plurality of marks formed on the mold, and a control unit configured to select the marks to be used in the imprint process based on positions of the marks on the mold, cause the observation unit to observe the selected marks before the imprint process is executed, and determine whether or not the imprint process is executable, based on an observation result.

Further features of the present invention will become apparent from the following description of embodiments with reference to the attached drawings.

### BRIEF DESCRIPTION OF THE DRAWINGS

FIG. 1 is a diagram illustrating an example of a configuration of an imprint apparatus.

FIG. 2 is a flowchart illustrating an example of a lot process using the imprint apparatus.

FIG. 3 is a flowchart illustrating an imprint process using the imprint apparatus.

FIGS. 4A to 4E are schematic views illustrating the imprint process using the imprint apparatus.

FIG. 5 is a view illustrating an example of a shot layout on a substrate.

FIGS. 6A and 6B are views illustrating a difference in marks to be used in an imprint process between a partial field and a full field.

FIG. 7 is a view illustrating an example of a layout of alignment marks in a pattern region of a mold.

FIGS. 8A to 8F are views illustrating an abnormality of an alignment mark of a mold 3.

FIG. 9 is a flowchart illustrating a lot process according to a first embodiment.

FIG. 10 is a flowchart illustrating a mark observation process according to the first embodiment.

FIGS. 11A to 11C are schematic views illustrating an operation of drive and observation of a TTM scope.

FIGS. 12A to 12C are schematic views illustrating an influence of aberration on a mark pattern.

FIG. 13 is a flowchart illustrating a mark observation process according to a second embodiment.

FIG. 14 is a flowchart illustrating an imprint process according to the second embodiment.

FIGS. 15A to 15F are views illustrating an article manufacturing method.

### DESCRIPTION OF THE EMBODIMENTS

Hereinafter, with reference to the accompanying drawings, favorable modes of the present invention will be described using Embodiments. In each diagram, the same reference signs are applied to the same members or elements, and duplicate description will be omitted or simplified.

### First Embodiment

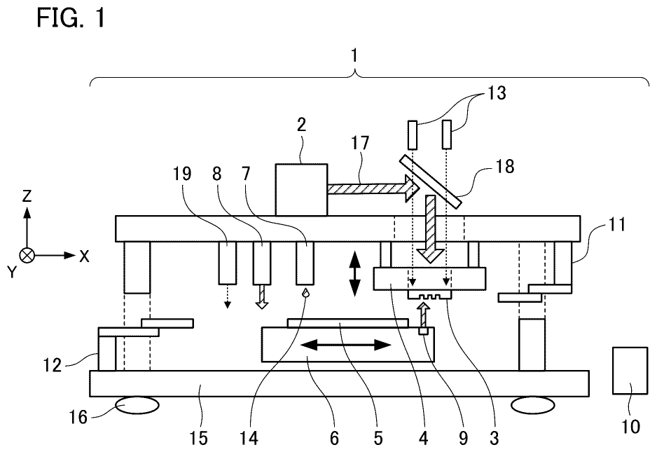

FIG. 1 is a view illustrating a configuration of an imprint apparatus. In a first embodiment, the imprint apparatus 1 is a processing apparatus that transfers a protruding/recessed pattern of a mold 3 as an original plate to a substrate 5 to be used in a semiconductor device manufacturing process and is an apparatus that employs a photo-curing method using ultraviolet light among imprint techniques.

In FIG. 1, a direction parallel to an irradiation direction of ultraviolet light 17 with respect to the mold 3 is defined as a Z direction, a direction in which the substrate 5 moves within a plane perpendicular to the Z direction is defined as an X direction, and a direction perpendicular to an X axis is defined as a Y direction.

The imprint apparatus 1 of the first embodiment includes an illumination system unit 2, an imprint head 4 that holds the mold 3, a substrate stage 6 that holds the substrate 5, an imprint material distributing device 7, a mold conveyance device 11, a substrate conveyance device 12, and a control device 10.

The illumination system unit 2 irradiates the mold 3 with the ultraviolet light 17 during an imprint process (also referred to as a transfer process). The illumination system unit 2 includes a light source and a plurality of optical elements that adjust ultraviolet light emitted from the light source to light appropriate for imprinting. The ultraviolet light 17 emitted from the illumination system unit 2 is reflected by a half mirror 18 directly above the imprint head 4 and cures an imprint material 14 on the substrate 5 through the mold 3.

The mold 3 is a mold in which a predetermined protruding/recessed pattern is formed on a surface facing the substrate 5 in a three-dimensional shape. The mold 3 has, for example, a rectangular peripheral portion, has a pattern region where the predetermined protruding/recessed pattern is formed on the surface facing the substrate 5 in a three-dimensional shape, and is made of a material (quartz or the like) that transmits ultraviolet light.

The imprint head 4 is a mold holding unit that holds and fixes the mold 3. The imprint head 4 has a Z direction drive mechanism for pressing the mold 3 against the imprint material 14 on the substrate 5 in a state of holding the mold 3. The imprint head 4 also has a tilt correction drive mechanism that tilts the entire mold 3 according to a tilt of the substrate 5 or the mold 3.

A through-the-mold (TTM) scope 13 is provided above the half mirror 18 above the mold 3. The TTM scope 13 is an alignment scope having an optical system and an imaging system for observing alignment marks provided on the mold 3 and alignment marks provided on the substrate 5.

The optical system includes a light source that emits light with which the alignment marks are irradiated, a wavelength filter that selects a wavelength of light emitted from the light source, and an ND filter that adjusts the intensity of light of the light source. The imaging system includes a light-receiving element, such as an image sensor.

Relative positional deviation amounts in the X direction and the Y direction can be measured by observing, with the TTM scope 13, a state in which the alignment marks provided on the mold 3 and the alignment marks provided on the substrate 5 overlap each other.

That is, the TTM scope 13 functions as an observation unit that measures a positional deviation amount between the alignment marks formed on the mold 3 and the alignment marks formed on the substrate 5 in the imprint process.

The imprint apparatus 1 of FIG. 1 has four TTM scopes 13 mounted thereon. A plurality of TTM scopes are disposed, so that a plurality of alignment marks can be measured at the same time, and not only the deviation amounts in the X and Y directions but also deviation amounts in a rotation direction and a magnification direction can be measured.

In the mold 3, it is assumed that the design position coordinates of the alignment marks are different depending on transfer pattern design. For this reason, it is desirable that the TTM scope 13 has a mechanism that drives the TTM scope in the X and Y directions.

As in the first embodiment, if a plurality of TTM scopes 13 are disposed in the imprint apparatus 1, it is desirable that each TTM scope is independently driven in the X and Y directions.

The substrate 5 is a substrate to which the protruding/recessed pattern is transferred, and includes, for example, a single crystal silicon substrate or a silicon on insulator (SOI) substrate.

The substrate stage 6 is a substrate holding unit that holds the substrate 5 by, for example, vacuum suction or electrostatic suction and is freely movable within the XY plane. It is desirable that the substrate stage 6 is provided with a rotational drive mechanism around a Z axis. Furthermore, a rotation mechanism around the Z direction or the X and Y axes may be provided and used as a substitute for the Z direction drive or tilt correction drive mechanism of the imprint head 4.

In the substrate stage 6, a mold height sensor 9 that can measure the surface of the mold 3 is mounted. The mold height sensor 9 can measure each position of the surface of the mold 3 while driving the substrate stage along the XY plane.

The substrate stage 6 is driven along a substrate stage surface plate 15. In this case, a reference of the Z direction or the tilt when the substrate stage is driven in the X and Y directions is the substrate stage surface plate 15.

The substrate stage surface plate 15 has a structure of being insulated from vibration from a floor by a substrate stage surface plate mount 16. In the example of the imprint apparatus 1 of FIG. 1, the entire apparatus is configured on the mount, so that a structure in which there is no influence of the vibration from the floor is provided.

A substrate height sensor 8 is a sensor that can measure the surface of the substrate 5 to measure a substrate height. The substrate stage 6 is driven in the X and Y directions, so that the height of each position of the substrate 5 can be measured.

The imprint material distributing device 7 is a distributing unit that distributes the uncured imprint material 14 on the substrate 5.

For the imprint material 14, a curable composition (also referred to as resin in an uncured state) that is cured by receiving energy for curing is used. As the energy for curing, electromagnetic wave, heat, or the like is used.

As the electromagnetic wave, for example, light such as infrared light, visible light, or ultraviolet light selected from a range of a wavelength equal to or greater than 10 nm and equal to or less than 1 mm is used. In the first embodiment, an example where ultraviolet light is used as the energy for curing will be described.

That is, in the first embodiment, the imprint material 14 is photo-curable resin that is cured by receiving the ultraviolet light 17 from the illumination system unit 2. The imprint material 14 may be thermoplastic or thermosetting resin.

The curable composition is a composition that is cured by irradiation of light or heating. The photo-curable composition that is cured by irradiation of light contains at least a polymerizable compound and a photopolymerization initiator, and may contain a nonpolymerizable compound or a solvent as needed. The nonpolymerizable compound is at least one material selected from a group consisting of a sensitizer, a hydrogen donor, an internal mold release agent, a surfactant, an antioxidant, a polymer component, and the like.

An off axis scope (OAS) 19 is a detection mechanism that measures the marks on the substrate 5. Because the marks on the substrate 5 can be measured by driving the substrate stage 6 in the X and Y directions, the OAS 19 does not require a drive mechanism in the X and Y direction unlike the TTM scope 13.

Because the OAS 19 has a loose constraint in disposition compared to the TTM scope 13, a scope that is optically advantageous is easily mounted. A wide field of view and a high measurement resolution can also be achieved.

The mold conveyance device 11 is a conveyance unit that conveys the mold 3 and places the mold 3 with respect to the imprint head 4.

The substrate conveyance device 12 is a conveyance unit that conveys the substrate 5 and places the substrate 5 with respect to the substrate stage 6.

The control device 10 is a control unit that operates each constituent unit of the imprint apparatus 1 and acquires sensor values and the like. The control device 10 is configured with a computer (not illustrated) or a sequencer connected to each unit of the imprint apparatus 1 with a line, and includes a central processing unit (CPU), a memory (storage unit), and the like.

The control device 10 comprehensively controls operation adjustment and the like of each constituent element of the entire imprint apparatus 1 according to a program stored in the memory. The control device 10 may be configured integrally with other portions of the imprint apparatus 1 (in a common housing). In addition, the control device may be configured separately from other portions of the imprint apparatus 1 (in another housing) or may be provided at a place different from the imprint apparatus 1 and may be remotely controlled.

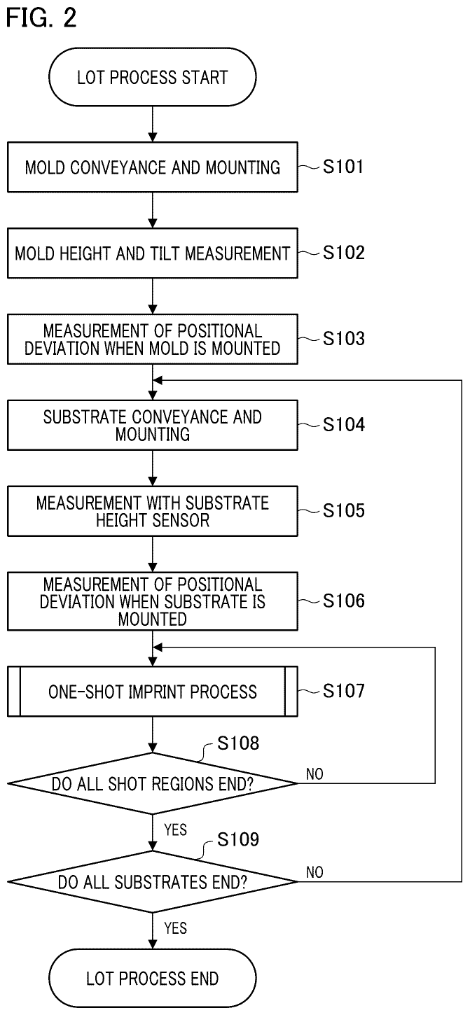

An imprint method using the imprint apparatus 1 of FIG. 1 will be described with reference to FIG. 2. FIG. 2 is a flowchart illustrating an example of a lot process using the imprint apparatus 1. The lot process is a series of imprint processes in one lot, and a plurality of substrates are included in one lot. Each operation (step) illustrated in the flowchart may be executed under the control of the CPU of the control device 10.

In S101, the mold 3 to be used from now on is mounted on the imprint head 4 by the mold conveyance device 11. In this case, the mold 3 is chucked to the imprint head 4 by vacuum suction or the like.

In S102, the surface of the mold 3 is measured by the mold height sensor 9. Such information is transmitted to the control device 10, and a drive amount in the Z direction of the imprint head 4 during the imprint process is determined.

The tilt of the surface of the mold 3 is calculated by measuring the surface heights of a plurality of points of the surface of the mold 3, and is used in determining a tilt amount for tilting the imprint head 4 such that the surfaces of the mold 3 and the substrate 5 are parallel to each other. Details of the imprint process will be described below.

In S103, a positional deviation amount when the mold 3 is mounted is measured using the TTM scope 13. In other words, a positional deviation amount of the mold 3 with respect to the imprint head 4 is measured. The TTM scope 13 is driven in the X and Y direction based on the design position coordinates of the alignment marks, so that the alignment marks enter the field of view of the TTM scope 13.

The position coordinates of the alignment marks are measured in this state. A deviation amount between the measured position coordinates and the design position coordinates is a positional deviation amount when the mold 3 is mounted.

Next, a process on the substrate 5 side will be described. In S104, the substrate 5 to be used is mounted on the substrate stage 6 by the substrate conveyance device 12. In this case, the substrate 5 is chucked to the substrate stage 6 by vacuum suction or the like.

In S105, a surface shape of the substrate 5 is measured by the substrate height sensor 8. Information of the surface shape of the substrate 5 is transmitted to the control device 10 and is used in calculating a height and a tilt of a region (or the surface) on the substrate 5 where a pattern is to be formed.

The control device 10 calculates the drive amount of the imprint head 4 in the Z direction during the imprint process and a drive amount for tilting the imprint head 4 such that the surfaces of the mold 3 and the substrate 5 are parallel to each other, from information of the surface shape of the substrate 5 and information of the height and the tilt of the mold 3 in S102.

In S106, positional deviations when the substrate 5 is mounted are measured by the OAS 19. In other words, positional deviations with respect to the substrate stage 6 when the substrate 5 is mounted on the substrate stage 6 are measured. A minimum of one point in each of the X and Y directions of the alignment marks disposed in each shot region on the substrate 5 is measured, so that the deviations in the X and Y directions when the substrate 5 is mounted can be measured.

Measurement of two points or more enables measurement of a rotation amount of the substrate 5. Measurement of more marks enables calculation of arrangement information of the shot regions on the substrate 5 from a calculation process such as function approximation.

In S107, an imprint process for one shot region is performed. Details will be described below.

In S108, determination is made whether or not the imprint process ends on all shot regions on the substrate, and if there is an unprocessed shot (No), S107 is repeated, and the imprint process of all shot regions is executed. If determination is made that the imprint process on all shots ends (Yes), the process of the substrate ends.

In S109, if there is an unprocessed substrate in the lot (No), the process from the conveyance of S104 is repeated on the next substrate. If the process of all substrates is completed (Yes), the lot process ends.

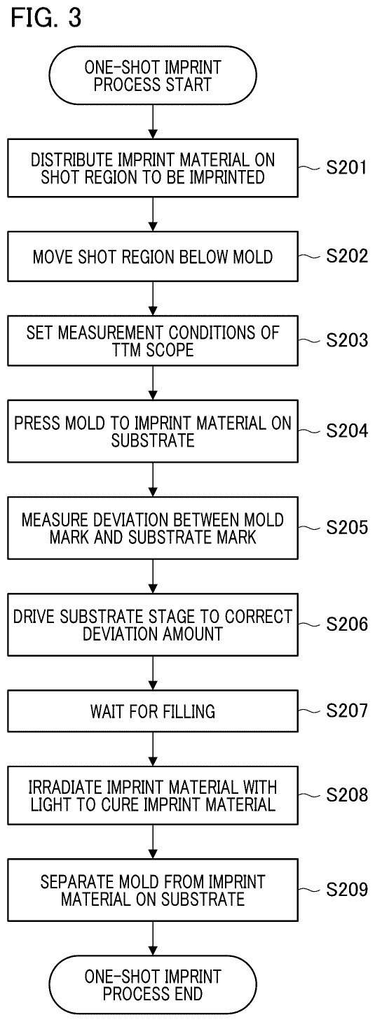

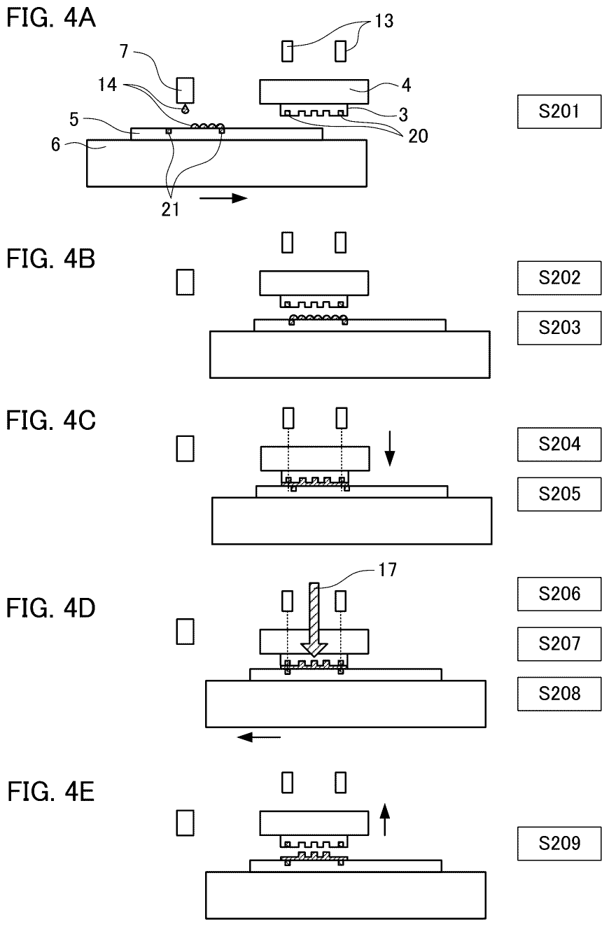

Next, the one-shot imprint process in S107 of FIG. 2 will be described in detail with reference to FIGS. 3 and 4A to 4E. In the one-shot imprint process, the imprint process for one shot region on the substrate 5 is executed. FIG. 3 is a flowchart illustrating the imprint process using the imprint apparatus 1.

Each operation (step) illustrated in the flowchart may be executed under the control of the CPU of the control device 10. FIGS. 4A to 4E are schematic views illustrating the imprint process using the imprint apparatus 1.

In S201, the imprint material 14 is distributed on the shot region on which the imprint process is executed, by the imprint material distributing device 7. The imprint material 14 is distributed on the surface of the substrate 5 as very small drops.

A place where the drops are disposed in the shot region and an amount of drops are determined in advance according to a pattern to be imprinted (a pattern to be formed on the substrate) or the like. FIG. 4A is a schematic view illustrating S201.

After the imprint material 14 is distributed, in S202, the substrate stage 6 is driven such that the shot region as an imprint target comes directly below the mold 3.

In S203, measurement conditions such as the wavelength of the light source of the TTM scope 13, transmittance of the ND filter, a light-receiving time of the image sensor are set. The processes of S201 to S203 are not necessarily successively executed and may be executed in parallel to reduce a processing time. FIG. 4B is a schematic view illustrating S202 and S203.

In S204, the imprint head 4 is driven in the Z direction, and the mold 3 is pressed against the imprint material 14 distributed on the shot region (imprint process). The substrate stage 6 may be driven and the imprint material 14 distributed on the substrate 5 may be pressed against the mold 3, or both the substrate stage 6 and the imprint head 4 may be driven.

In S205, the marks 20 of the mold 3 and the marks 21 in the shot region on the substrate 5 are observed at the same time by the TTM scope 13, so that a relative positional deviation amount between the mold 3 and the shot region on the substrate 5 is measured. FIG. 4C is a schematic view illustrating S204 and S205.

In S206, the substrate stage 6 is driven to correct the relative positional deviation amount measured in S205.

In S207, the process waits for a time until a protruding/recessed portion of the mold 3 is sufficiently filled with the imprint material 14. In this case, S205 and S206 may be alternately repeated within the waiting time in S207. Alternatively, the process transits to S208 while waiting for a later one of a time until a measurement result in S205 falls within an allowable range and a time until the protruding/recessed portion is filled with the imprint material 14 in S207.

In S208, the imprint material 14 of the substrate is irradiated with the ultraviolet light 17 from the illumination system unit 2 and is cured. FIG. 4D is a schematic view illustrating S206 to S208.

In S209, the imprint head 4 is lifted upward, and the mold 3 and the substrate 5 are separated. FIG. 4E is a schematic view illustrating S209. Here, similarly to S204, the substrate stage 6 may be driven or both the substrate stage 6 and the imprint head 4 may be driven.

As a result, the protruding/recessed pattern of the mold 3 is transferred (formed) to the shot region of the substrate 5. The above is a basic lot process flow using the imprint apparatus 1 according to the first embodiment.

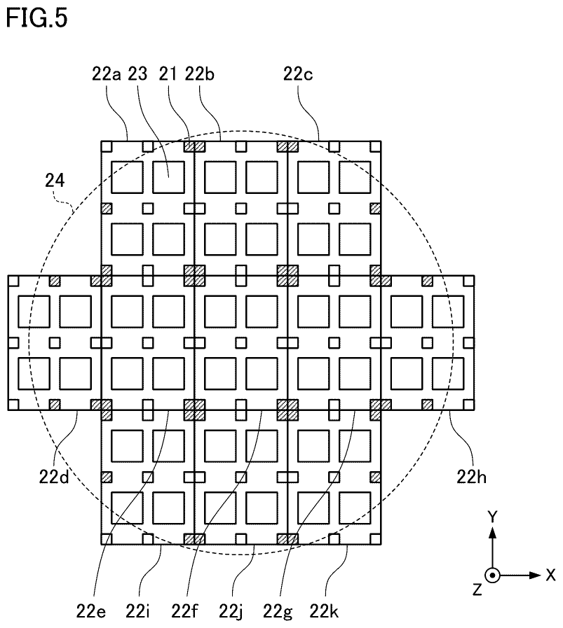

FIG. 5 is a view illustrating an example of a shot layout on the substrate 5. Specifically, the present view illustrates a shot layout in which a plurality of shot regions 22a to 22k in the direction of the XY plane of the substrate 5.

The shot region means a region having a size corresponding to a pattern region 25 of the mold 3 described below in the first embodiment, that is, a region (molding region) where a pattern of an imprint material corresponding to the pattern region 25 of the mold 3 in one imprint process.

A mark group including a plurality of alignment marks represented by the mark 21 is disposed at nine places in each of the shot regions 22a to 22k. The mark 21 is a substrate-side mark formed on the substrate 5 side and is a mark for measuring a relative positional deviation amount of each of the shot regions 22a to 22k with respect to the mold 3.

In the mark 21, a mark pattern is formed. The mark pattern of the mark 21 and a mark pattern of the mark 20 on the mold 3 are superposed such that a moire image can be detected, and the relative positional deviation amount can be measured from the detected moire image.

Hatched marks in the mark group represented by the mark 21 illustrated in FIG. 5 are marks that are actually used to measure the relative positional deviation amount during the imprint process. A region group represented by a pattern transferred region 23 is disposed at four places in each of the shot regions 22a to 22k.

The imprint material 14 distributed on the pattern transferred region 23 is imprinted with pattern transfer regions of the mold 3 described below, so that patterns are transferred on the substrate 5. In regard to the shot regions 22a to 22k and the marks 21 illustrated in FIG. 5, a shape and a size of the pattern transferred region 23, the disposition of the pattern transferred regions 23, and the number of pattern transferred regions 23 to be disposed are an example and are limited thereto.

Actually, the shot regions are disposed in various shot layout patterns according to user setting. Furthermore, the disposition of the alignment marks in the shot region or the mark pattern of the alignment mark is different according to the setting.

An imprint region 24 indicated by a broken line is a region on the substrate 5 where the imprint material 14 is distributed, and is a region where the mark 21 can be disposed or a pattern can be formed through the imprint process. In the imprint region 24, the shot regions 22a to 22k are arranged and formed with no gap. This is because it is advantageous to form as many shot regions as possible on one substrate from a point of throughput.

Like the shot regions 22a, 22c, 22d, 22h, 22i, and 22k, a shot region that is not fully included within the imprint region 24 is referred to as a partial field.

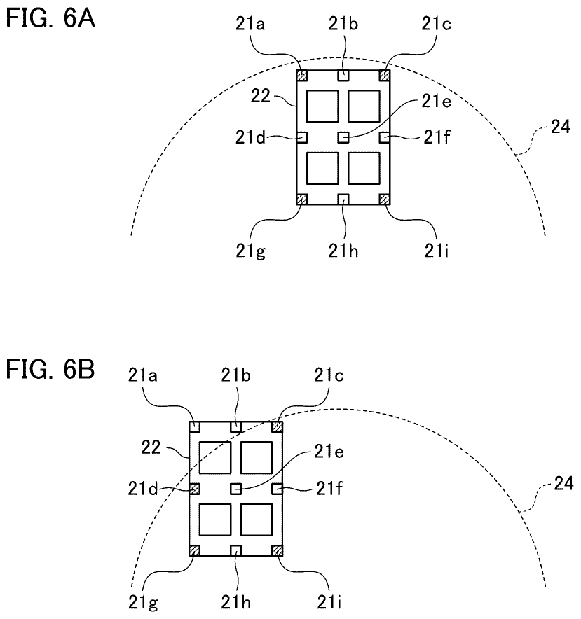

In contrast, like the shot regions 22b, 22e, 22f, 22g, and 22j, a shot region that is fully included in the imprint region 24 is referred to as a full field. Marks to be used for the measurement of the relative positional deviation amount in a shot region are different between the partial field and the full field. This will be described with reference to FIGS. 6A and 6B.

FIGS. 6A and 6B are views illustrating a difference in marks to be used in an imprint process between a partial field and a full field. FIG. 6A is a view illustrating marks to be used in an imprint process of a full field. FIG. 6B is a view illustrating marks to be used in an imprint process of a partial field.

In the shot regions 22 of FIGS. 6A and 6B, marks 21a to 21i are disposed. The marks 21a to 21i are alignment marks that are used for detecting the relative positional deviation amount between the mold 3 and the substrate 5.

Because the alignment marks that are used for the measurement of the relative positional deviation amount need to be in the imprint region 24, should be selected from among the marks in the imprint region 24 and in the shot region 22. Furthermore, as the alignment marks that are used for the measurement of the relative positional deviation amount, marks with which the measurement accuracy of the positional deviation amount is as high as possible are preferably selected.

For this reason, as illustrated in FIG. 6A, if a shot region to be a target of an imprint process is a full field, marks 21a, 21c, 21g, and 21i that are positioned at four corners of the shot region 22 and indicated by oblique lines are preferably used for the measurement of the relative positional deviation amount.

On the other hand, as illustrated in FIG. 6B, if a shot region to be a target of an imprint process is a partial field, because marks 21a and 21b are outside the imprint region 24, the marks 21a and 21b cannot be used for the measurement of the relative positional deviation amount. Therefore, marks 21c, 21d, 21g, and 21i indicated by oblique lines are preferably used for the measurement of the relative positional deviation amount.

As illustrated by the hatched marks of FIGS. 6A and 6B, position coordinates in the shot region of the marks to be used for the measurement of the relative positional deviation amount are different between the full field and the partial field. Furthermore, like the shot region 22a and the shot region 22c of FIG. 5, for the shots where position coordinates of the marks outside the imprint region 24 are different among the shots as the partial field, position coordinates of the marks to be used for the measurement of the deviation amount are different.

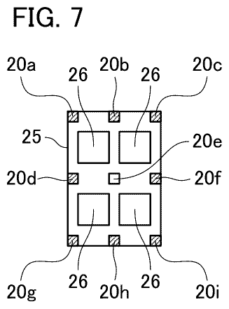

Subsequently, a layout of alignment marks in a pattern region of the mold 3 will be described with reference to FIG. 7. FIG. 7 is a view illustrating an example of a layout of alignment marks in a pattern region of the mold 3. A pattern region 25 is a region corresponding to the shot region 22 on the substrate 5.

Marks 20a to 20i are alignment marks that are disposed in the pattern region 25, and are disposed at nine places. Furthermore, the marks 20a to 20i are mold-side marks formed on the mold 3 side, and have mark patterns formed for measuring the relative positional deviation amount. Position coordinates in the shot region of the marks 20a to 20i correspond to position coordinates of the marks 21 of each shot region on the substrate 5.

Pattern transfer regions 26 are disposed at four places in the pattern region 25. The pattern region 25 of the mold 3 is imprinted in the shot region 22 of the substrate 5, so that the patterns formed in the pattern transfer regions 26 are transferred to the pattern transferred regions 23.

If the pattern region 25 of the mold 3 is imprinted in the shot regions 22a to 22k on the substrate 5 illustrated in FIG. 5, alignment needs to be performed with respect to each of the shot regions 22a to 22k. To perform alignment for each shot region, alignment marks that are normally detectable need to exist in position coordinates on the mold 3 corresponding to the alignment marks to be used for the measurement of the relative positional deviation amount of all shot regions of the substrate 5.

For this reason, marks to be used for alignment among the alignment marks on the mold 3 are all marks excluding the mark 20e among the marks 20a to 20i as indicated by oblique lines in FIG. 7.

As illustrated in FIG. 3, the measurement of the relative positional deviation amount between the mold 3 and the shot region on the substrate 5 is performed with measurement condition setting (S203) of the TTM scope 13 in the one-shot imprint process (S107). In this case, if an abnormality occurs in the measurement of the relative positional deviation amount, the imprint process cannot be normally executed.

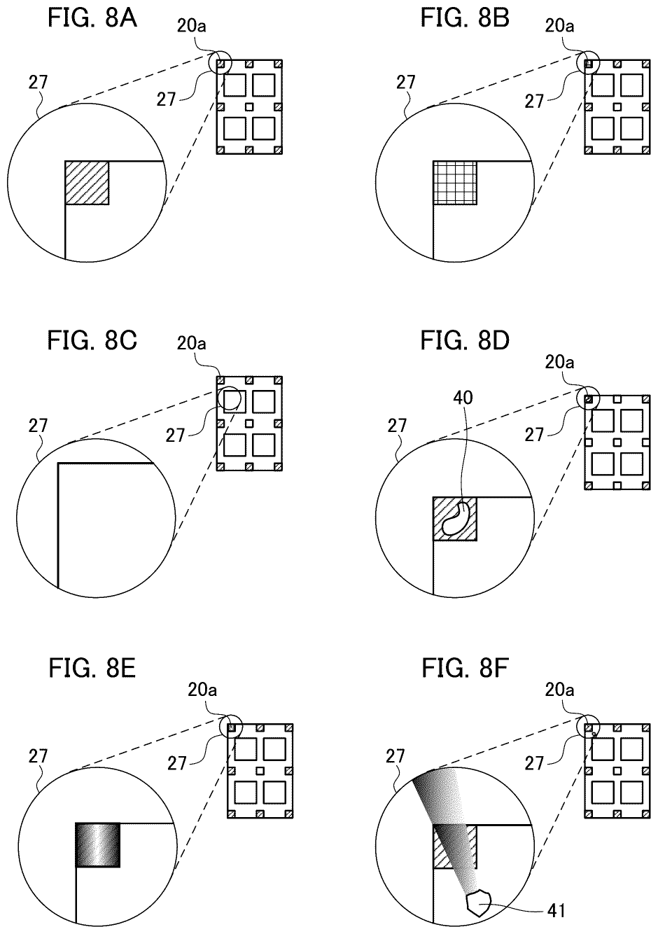

An example of a major cause why the measurement of the relative positional deviation amount cannot be correctly performed is a case where the alignment mark of the mold 3 is abnormal. A case where an abnormality may occur in a mark will be described with reference to FIGS. 8A to 8F with the mark 20a of the mold 3 illustrated in FIG. 7 as an example.

FIGS. 8A to 8F are views illustrating an abnormality of the alignment mark of the mold 3. In the present views, each alignment mark will be described by displaying an imaging area 27 of the TTM scope 13 on an enlarged scale. FIG. 8A is a view illustrating an example where detection of an alignment mark is normally performed.

An oblique line portion in the mark 20a of the present view schematically illustrates a mark pattern. The mark 20a illustrated in FIG. 8A is formed on the mold 3 as design information extracted from recipe information. The recipe information includes the design information, and the design information includes design position coordinates as positional information of the alignment mark and mark pattern information formed in the mark.

In contrast, FIGS. 8B to 8F are cases where detection of an alignment mark is abnormal. FIG. 8B is a view illustrating a first example where detection of an alignment mark is abnormal. The present view illustrates a case where an actual mark pattern of the mark 20a of the mold 3 is different from mark pattern information of the mark 20a registered in the recipe. In this case, because the mark pattern of the mold 3 is not as the design information, the alignment mark cannot be recognized.

FIG. 8C is a view illustrating a second example where detection of an alignment mark is abnormal. The present view illustrates a case where actual position coordinates of the mark 20a of the mold 3 are different from the design position coordinates of the mark 20a registered in the recipe. In this case, because the mark 20a cannot be observed with the imaging area 27 of the TTM scope, the measurement of the positional deviation amount cannot be performed.

FIG. 8D is a view illustrating a third example where detection of an alignment mark is abnormal. The present view illustrates a case where an actual mark pattern of the mark 20a of the mold 3 has a defect 40 and a moire image cannot be normally recognized. Such a case may occur if foreign matter is stuck to the mark on the mold due to the imprint process, or the like.

FIG. 8E is a view illustrating a fourth example where detection of an alignment mark is abnormal. The present view illustrates a case where a mark pattern is peeled due to cleaning of the mold and is detected as a pattern different from the mark pattern of the design information. In this case, in the detection of the alignment mark, the mark pattern is recognized to be abnormal.

FIG. 8F is a view illustrating a fifth example where detection of an alignment mark is abnormal. The present view illustrates a case where a mark pattern cannot be correctly detected due to an influence of unexpected reflected light, scattered light, or the like caused by foreign matter 41 stuck around an alignment mark. In this case, even if foreign matter is not directly stuck to an alignment mark, there is a case where a detection abnormality may occur.

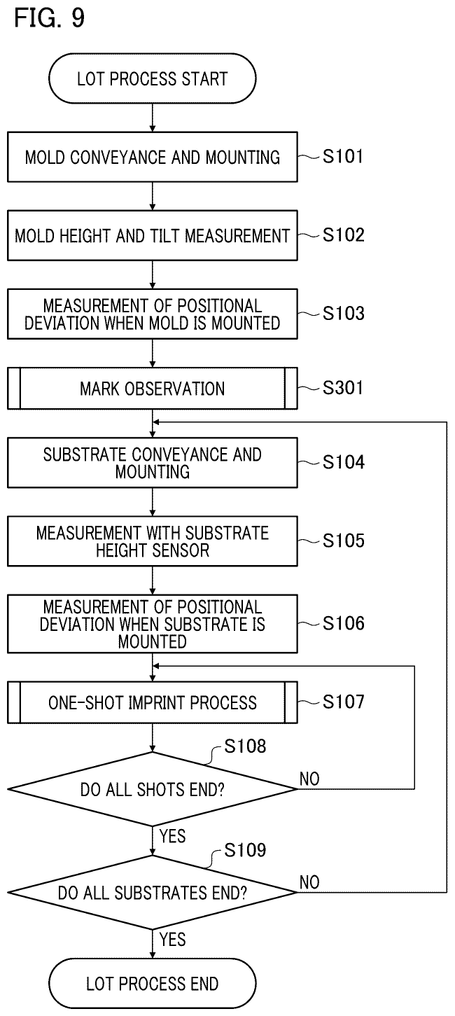

A lot process for preventing the occurrence of the detection abnormality in the alignment mark of the mold 3 as represented in FIGS. 8B to 8F will be described with reference to FIG. 9. In the present view, the same steps as those in FIG. 2 are represented by the same reference numerals, and description thereof will not be repeated. Only differences from the steps in FIG. 2 will be described in detail.

FIG. 9 is a flowchart illustrating a lot process according to the first embodiment. Each operation (step) illustrated in the flowchart may be executed under the control of the CPU of the control device 10.

After the processes of S101 to S103, in S301, observation of the alignment marks of the mold 3 to be used for the measurement of the relative positional deviation amount between the mold 3 and the substrate 5 in the imprint process is performed using the TTM scope 13.

That is, the control device 10 causes the TTM scope 13 to observe the alignment marks on the mold 3. Thereafter, if the observation of all alignment marks to be used is completed, substrate conveyance and mounting (S104) are performed. In this case, mark observation (S301) is not necessarily performed immediately before substrate conveyance and mounting (S104).

As long as the mark observation is performed at the timing before the one-shot imprint process (S107) is executed, the effects of the present invention can be obtained. The mark observation (S301) is preferably performed after the positional deviation amount of the mold 3 held by the imprint head 4 is measured in S103.

Note that the mark observation may be performed before S103 as long as the mold 3 can be mounted on the imprint head 4 in a state in which there is no positional deviation amount of the mold 3 with respect to the imprint head 4.

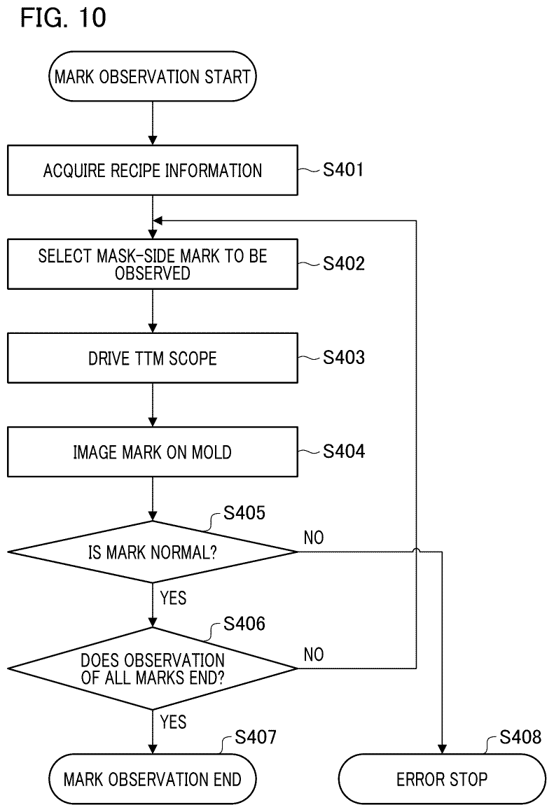

A detailed process of the mark observation (S301) will be described from now on with reference to FIG. 10. FIG. 10 is a flowchart illustrating a mark observation process according to the first embodiment. Each operation (step) illustrated in the flowchart may be executed under the control of the CPU of the control device 10.

After the mark observation starts, in S401, the control device 10 acquires the recipe information. Specifically, the control device 10 acquires layout information of the shot regions on the substrate 5 registered in the recipe by the user, the design position coordinates of the alignment marks to be used, and the mark pattern information.

In S402, the control device 10 selects the marks 20 required for the imprint process based on the position coordinates (positional information) of the marks on the substrate 5 acquired from the recipe information and the mark pattern information.

Specifically, the control device 10 selects the mark 20 to be used to detect the relative positional deviation amount between the mold 3 and the substrate 5 in the imprint process using the recipe information. Here, while the marks 20 to be used in the imprint process are selected using the recipe information, the present invention is not limited thereto.

For example, a table in which the marks to be used in the imprint process are associated with a lot number attached to each lot may be stored in the control device 10 in advance, and the marks 20 to be used in the imprint process may be selected using the table.

An order of observing the marks is determined. In this case, while the order of observing the marks is not constrained, to reduce a processing time of the mark observation, the order of observing the marks is set to an order in which a drive time of the TTM scope 13 is equal to or less than a threshold, and preferably, is shortest.

If a plurality of marks are observed at the same time with a plurality of TTM scopes 13, a combination of the TTM scope 13 and the mark to be observed may be limited to the same combination when the imprint process is executed.

For example, if light amount setting optimum for mark observation is different for each TTM scope 13, when the TTM scope 13 to be used is different between the mark observation and the imprint process, a detection result of a mark pattern is likely to be different depending on a difference in light amount.

For this reason, in such a case, it is preferable that the mark pattern is observed with the same combination as in the imprint process, so that the determination accuracy of the pattern is increased. In other words, it is preferable that, during the execution of the imprint process, the TTM scope 13 observes the same mark as the mark observed before the execution of the imprint process.

In S403, the control device 10 drives the TTM scope 13 with respect to the mark position coordinates based on the design position coordinates of the mark to be observed. If a plurality of TTM scopes 13 are mounted in the imprint apparatus 1, it is preferable that a plurality of TTM scopes are driven to the design position coordinates of a plurality of marks to be observed at the same time and alignment is performed.

A drive processing time can be reduced by driving the TTM scopes at the same time. In the first embodiment, because the imprint apparatus 1 has four TTM scopes 13 mounted thereon, the four TTM scopes 13 are driven, and the centers of the imaging areas of the TTM scopes 13 are aligned with the design position coordinates of four marks on the mold 3.

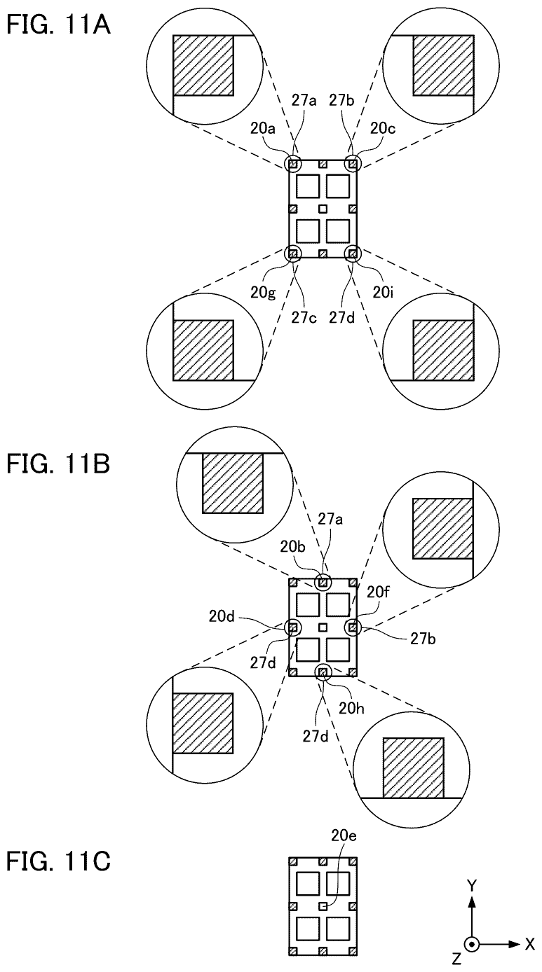

The operation of drive and observation of the TTM scope 13 will be described from now on with reference to the flow of FIG. 10 and schematic views of FIGS. 11A to 11C. FIGS. 11A to 11C are schematic views illustrating the operation of drive and observation of the TTM scope 13.

FIG. 11A illustrates a state in which center positions of imaging areas 27a, 27b, 27c, and 27d of four TTM scopes 13 are driven to position coordinates of the marks 20a, 20c, 20g, and 20i of the mold 3 to be observed.

To perform the mark observation, the TTM scope 13 needs to be focused on the mark pattern. For this reason, the focus adjustment of the TTM scope 13 is performed by driving the TTM scope in the X and Y directions and in the Z direction as needed.

In S404 of FIG. 10, imaging of the alignment mark on the mold 3 is performed by the TTM scope 13. Then, the control device 10 analyzes an image in the imaging area captured by the TTM scope 13. Specifically, mark pattern information obtained with imaging is compared with the mark pattern information registered in the recipe by image recognition.

In S405, the control device 10 determines whether or not the imprint process is executable, based on an observation result of the alignment mark on the mold 3. Specifically, the control device 10 determines whether or not the imprint process is executable, based on a comparison result of the mark pattern information. That is, here, the observation result of the alignment mark on the mold 3 includes information about whether or not a mark pattern matching the recipe information is observed.

The control device 10 determines that mark detection is abnormal (No) if determination is made that the target mark is not included in the imaging area of the TTM scope 13 or if the pattern of the mark does not match the mark pattern acquired with the recipe information.

That is, the control device 10 determines that the imprint process is not executable. In this case, the mark observation ends abnormally, and the mark observation flow ends. A notification of an observation abnormality of the alignment mark is issued to the user with a buzzer or display on an operation panel, and a lot process sequence is stopped with error (S408).

That is, if determination is made that the imprint process is executable as a result of determining whether or not the imprint process is executable, the control device 10 issues a notification of a mark abnormality. On the other hand, if the mark pattern observed within the imaging area of the TTM scope 13 matches the mark pattern acquired with the recipe information, determination is made that mark detection is normally performed (Yes). That is, the control device 10 determines that the imprint process is executable, and proceeds to a process of S406.

In S406, the control device 10 determines whether or not the observation of all alignment marks to be used in the imprint process ends. If there is an unobserved mark on the mold (No), the control device 10 returns to S402 to drive the TTM scope 13 to the position coordinates of the unobserved mark, and selects a next mark to be observed.

FIG. 11B illustrates a state in which the center positions of the imaging areas 27a, 27b, 27c, and 27d of the TTM scopes 13 are driven to the position coordinates of the unobserved marks 20b, 20d, 20f, and 20h on the mold 3 to be next observed from the state of FIG. 11A. To reduce the drive processing time of the TTM scope 13 to the minimum, the TTM scope 13 is driven to the state of FIG. 11B such that the drive amount from the state of FIG. 11A becomes minimum.

FIG. 11C illustrates a state after the mark observation ends in the state of FIG. 11B. Because the mark 20e is not a mark to be observed, the TTM scope 13 does not need to be driven. In the state of FIG. 11C, because an unobserved mark does not exist on the mold 3, the mark observation ends (FIG. 10, S407).

As described above, according to the first embodiment, the alignment marks on the mold to be used in the imprint process are observed before the execution of the imprint process, so that an abnormality in the alignment marks can be detected in advance and the occurrence of rework can be reduced.

### Second Embodiment

In a second embodiment, as another utilization example of the mark observation result illustrated in FIG. 10 of the first embodiment, a method that acquires a relative positional deviation amount of a center position of an alignment mark with respect to the center position of the imaging area of the TTM scope 13, and corrects a relative positional deviation will be described.

In the imaging of the alignment mark on the mold in S404 illustrated in FIG. 10, when the TTM scope 13 is driven to the position coordinates of the mark to be observed on the mold, the center position of the mark may deviate with respect to the center position of the imaging area of the TTM scope 13.

This occurs due to a reason such as a manufacturing error of the apparatus with respect to a design position or variation of the drive amount of the TTM scope 13. The TTM scope 13 is an optical scope that forms an image via a lens, and aberration occurs in an optical image formed on an imaging surface.

For this reason, if the mark pattern of the alignment mark is observed using the TTM scope 13, when a deviation occurs between the imaging area of the TTM scope 13 and the center position of the mark pattern, the image forming performance of the mark pattern formed on the imaging surface is deteriorated due to aberration.

The measurement of the positional deviation amount between the mold and the substrate is performed based on the detected mark pattern. For this reason, deterioration of the image forming performance of the mark pattern results in deterioration of the accuracy of the measurement of the positional deviation amount between the mold and the substrate during the imprint process.

Because requested accuracy of alignment of the mold and the substrate in the imprint apparatus is an order of nm, deterioration of alignment accuracy due to aberration is apparent as a non-negligible problem.

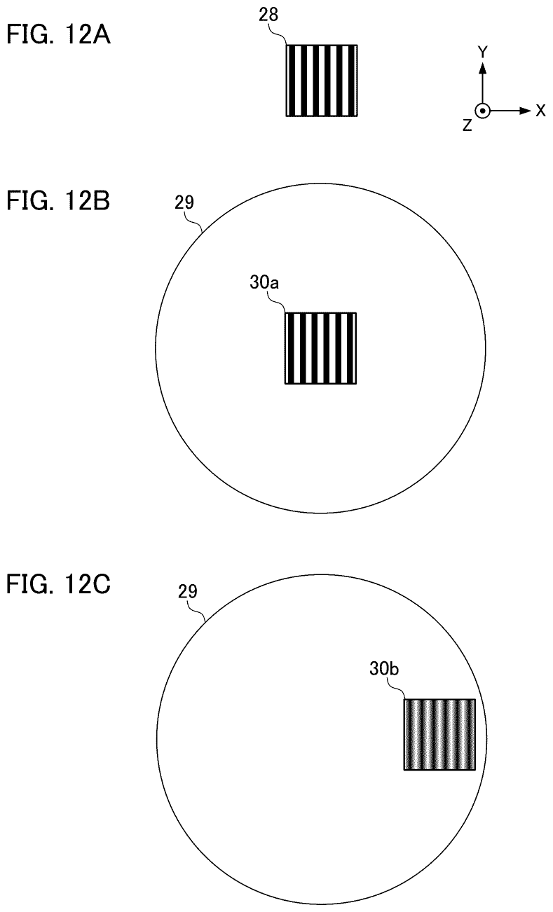

Here, an influence of aberration on a mark pattern will be described with reference to FIGS. 12A to 12C. FIGS. 12A to 12C are schematic views illustrating an influence of aberration on a mark pattern. FIG. 12A is a schematic view illustrating an alignment mark to be imaged having a mark pattern of a stripe pattern 28.

FIGS. 12B and 12C are schematic views illustrating an example of an imaging area 29 of the TTM scope 13. In FIGS. 12B and 12C, optical images 30a and 30b that are formed on an imaging surface when an alignment mark is imaged are schematically illustrated. In FIGS. 12A to 12C, it is assumed that the center of the imaging area of the TTM scope 13 is an optical center, and aberration decreases toward the optical center.

FIG. 12B illustrates an example where the center of the alignment mark is disposed to match the center of the imaging area of the TTM scope 13 on the XY plane. Because the entire region of the alignment mark is positioned near the center of the imaging area, there is almost no influence of aberration, and an optical image is formed with high accuracy.

On the other hand, FIG. 12C illustrates an example where the center of the alignment mark is disposed to be positioned at a point on the XY plane away from the center of the imaging area of the TTM scope 13. Because the entire region of the alignment mark is positioned near an end portion of the imaging area, there is a large influence of aberration, and an optical image with a blurred mark pattern is formed.

FIG. 12C illustrates an example of an influence of aberration on the optical image of the mark pattern, and actually, there are various influences of aberration on the optical image such as blur, distortion, and curvature depending on optical systems.

To reduce deterioration of the image forming performance due to aberration, the center of the mask pattern needs to be adjusted to overlap the center of the imaging area of the TTM scope 13. That is, the relative positional deviation is corrected such that the center of the imaging area of the TTM scope 13 and the center of the mark pattern match each other. As a result, deterioration of the image forming performance of the mark pattern and deterioration of the accuracy of the measurement of the relative positional deviation amount between the mold and the substrate can be prevented.

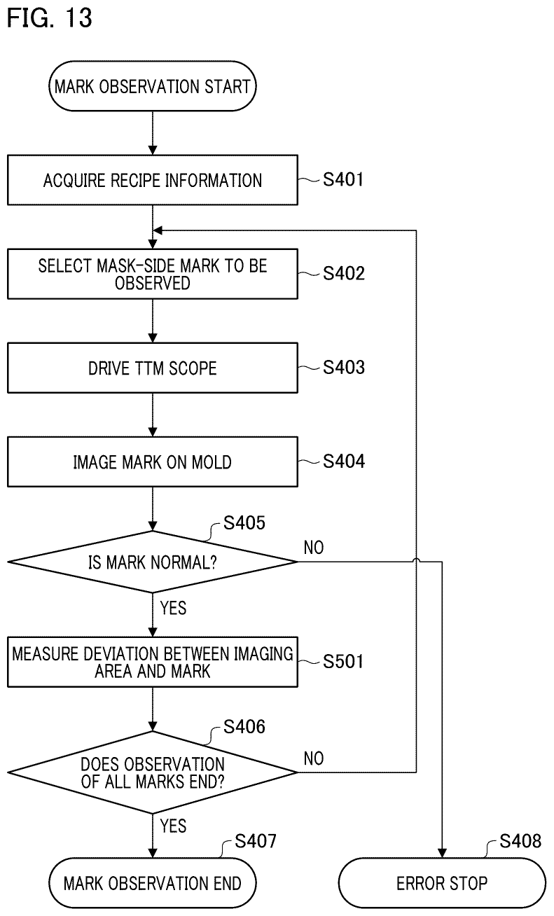

A process flow of measuring a relative positional deviation amount between the center of the imaging area and the center of the mark pattern will be described with reference to FIG. 13. FIG. 13 is a flowchart illustrating a mark observation process according to the second embodiment. Each operation (step) illustrated in the flowchart may be executed under the control of the CPU of the control device 10. In the present view, the same steps as those in FIG. 10 are represented by the same reference numerals, and description thereof will not be repeated. Only differences from the steps in FIG. 2 will be described in detail.

In S405, if the alignment mark is normally observed, subsequently, in S501, for example, the control device 10 measures and acquires a relative positional deviation amount between the center (optical center position) of the imaging area of the TTM scope 13 and the center position of the mark pattern.

Then, a measured value is stored as a correction value of a deviation amount. If a correction value of a deviation amount is acquired for all marks to be used in the imprint process, and the observation of all marks ends (S406, Yes), the mark observation ends (S407).

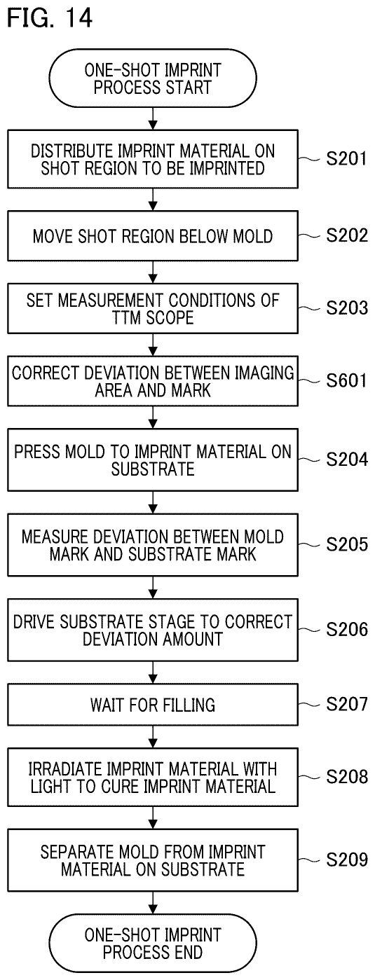

Subsequently, a process flow of correcting the relative positional deviation amount between the center of the imaging area and the center of the mark pattern will be described with reference to FIG. 14. FIG. 14 is a flowchart illustrating an imprint process according to the second embodiment.

Each operation (step) illustrated in the flowchart may be executed under the control of the CPU of the control device 10. In the present view, the same steps as those in FIG. 3 are represented by the same reference numerals, and description thereof will not be repeated. Only differences from the steps in FIG. 2 will be described in detail.

After the processes of S201 to S203 are executed, in S601, the relative positional deviation amount between the center of the imaging area and the center of the mark pattern is corrected. Specifically, the control device 10 drives the TTM scope 13 based on the correction value of the deviation amount acquired with the process of S501 in FIG. 13. After the relative positional deviation is corrected, the imprint head is lifted down to press the mold against the substrate (S204).

In the imprint apparatus of the die-by-die alignment method, first, a correction value of a deviation amount between the center of the imaging area and the center of the mark pattern is acquired in a previous shot. Then, in a next shot, a relative positional deviation amount can be corrected based on the correction value of the deviation amount acquired in the previous shot.

However, in regard to a first shot that is initially performed in the lot process, a measurement result of a previous shot does not exist, and as a result, correction based on the previous shot cannot be performed. If an image height of the alignment mark of the nest shot is different from the alignment mark of the previous shot, the correction value of the deviation amount of the previous shot cannot be applied.

In this way, if the correction value of the deviation amount of the previous shot does not exist or if the correction value of the deviation amount of the previous shot does not exist cannot be applied, a correction method according to the second embodiment is effectively employed.

As described above, according to the second embodiment, in the mark observation, the relative positional deviation amount between the center of the imaging area and the center of the mark pattern is acquired, and the deviation amount is corrected, so that the mold and the substrate can be aligned with high accuracy. With this, the occurrence of rework can be reduced.

### <Embodiment of Article Manufacturing Method>

A pattern of a cured product formed using the imprint apparatus is used permanently in at least a part of various articles or temporarily in manufacturing various articles. An article is an electric circuit element, an optical element, a MEMS, a recording element, a sensor, a mold, or the like.

Examples of the electric circuit element include a volatile or nonvolatile semiconductor memory such as a DRAM, an SRAM, a flash memory, or an MRAM, and a semiconductor memory element such as an LSI, a CCD, an image sensor, or an FPGA. An example of the mold is a mold for imprint.

The pattern of the cured product is used directly as at least a part of constituent members of the article or is used temporarily as a resist mark. After etching, ion implantation, or the like is performed in a processing step of the substrate, the resist mask is removed.

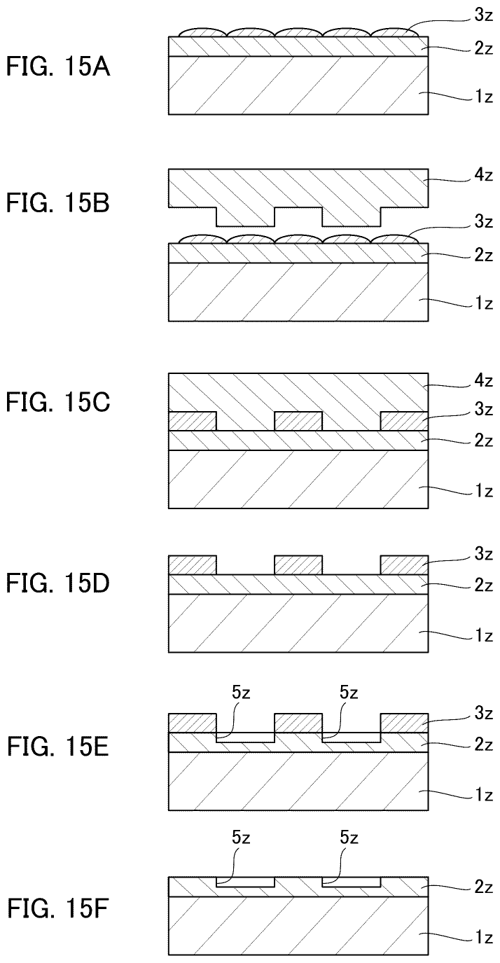

Next, a specific article manufacturing method will be described. As illustrated in FIG. 15A, a substrate 1z such as a silicon wafer with a processed material 2z such as an insulator formed on the surface is prepared, and subsequently, a composition 3z is applied to the surface of the processed material 2z by an inkjet method or the like. Here, a state in which the composition 3z is applied as a plurality of droplets onto the substrate is illustrated.

As illustrated in FIG. 15B, a side of a mold 4z for imprint on which the protruding/recessed pattern is formed is directed toward and made to face the composition 3z on the substrate. As illustrated in FIG. 15C, the substrate 1z to which the composition 3z is applied and the mold 4z are brought into contact with each other, and a pressure is applied. A gap between the mold 4z and the processed material 2z is filled with the composition 3z. In this state, if the composition 3z is irradiated with light as energy for curing via the mold 4z, the composition 3z is cured.

As illustrated in FIG. 15D, if the mold 4z and the substrate 1z are separated after the composition 3z is cured, a pattern of a cured product of the composition 3z is formed on the substrate 1z. The pattern of the cured product has a shape in which a recessed portion of the mold corresponds to a protruding portion of the cured product and a protruding portion of the mold corresponds to a recessed portion of the cured product, that is, the protruding/recessed pattern of the mold 4z is transferred to the composition 3z.

As illustrated in FIG. 15E, if etching is performed using the pattern of the cured product as an etching resistant mask, a portion of the surface of the processed material 2z where the cured product does not exist or remains thin is removed to form a groove 5z.

As illustrated in FIG. 15F, if the pattern of the cured product is removed, an article in which the groove 5z is formed in the surface of the processed material 2z can be obtained. Here, while the pattern of the cured product is removed, the pattern of the cured product may not be removed even after the process, and may be used as an interlayer insulating film included in a semiconductor element or the like, that is, a constituent member of an article.

Although an example where a mold for circuit pattern transfer with a protruding/recessed pattern is used as the mold 4z has been described, a mold (planar template) having a planar portion with no protruding/recessed pattern may be used.

While the present invention has been described with reference to exemplary embodiments, it is to be understood that the invention is not limited to the disclosed exemplary embodiments. The scope of the following claims is to be accorded the broadest interpretation to encompass all such modifications and equivalent structures and functions.

In addition, as a part or the whole of the control according to the embodiments, a computer program realizing the function of the embodiments described above may be supplied to the imprint apparatus or the like through a network or various storage media. Then, a computer (or a CPU, an MPU, or the like) of the imprint apparatus or the like may be configured to read and execute the program. In such a case, the program and the storage medium storing the program configure the present invention.

In addition, the present invention includes those realized using at least one processor or circuit configured to perform the functions of the embodiments explained above, for example. Dispersion processing may be performed using a plurality of processors.

This application claims the benefit of priority from Japanese Patent Application No. 2023-078614, filed on May 11, 2023, which is hereby incorporated by reference herein in its entirety.

What is claimed is:

1. An imprint apparatus that executes an imprint process of forming a pattern to an imprint material on a substrate using a mold, the imprint apparatus comprising:
at least one processor or circuit configured to function as:
an observation unit configured to observe a plurality of mold-side marks formed on the mold; and
a control unit configured to select the mold-side marks to be used in the imprint process, cause the observation unit to observe the selected mold-side marks before the imprint process is executed, and determine whether or not the imprint process is executable, based on an observation result.

2. The imprint apparatus according to claim 1,
wherein the control unit is configured to acquire positional information of a plurality of substrate-side marks formed on the substrate as a target of the imprint process and select the mold-side marks to be used in the imprint process using the acquired positional information.

3. The imprint apparatus according to claim 1,
wherein the control unit is configured to determine an order of the mold-side marks to be observed by the observation unit such that a drive time of the observation unit is equal to or less than a threshold.

4. The imprint apparatus according to claim 1,
wherein the at least one processor or circuit is further configured to function as: a drive unit configured to drive the observation unit, and
the control unit is configured to acquire a relative positional deviation amount of a center position of the mold-side marks with respect to an optical center position of an imaging area of the observation unit based on the observation result and to drive the observation unit to correct the relative positional deviation amount.

5. The imprint apparatus according to claim 1,
wherein the control unit is configured to select the mold-side marks to be used to detect a relative positional deviation amount between the mold and the substrate in the imprint process.

6. The imprint apparatus according to claim 1,
wherein the at least one processor or circuit is further configured to function as: a plurality of observation units,
the observation units are configured to observe the same mold-side marks as the mold-side marks observed before the execution of the imprint process even during the execution of the imprint process.

7. The imprint apparatus according to claim 1,
wherein the control unit is configured to acquire recipe information including pattern information of the mold-side mark, and
the observation result includes information about whether or not a mark pattern matching the recipe information is observed from the mold-side mark in an imaging area of the observation unit.

8. The imprint apparatus according to claim 1,
wherein the control unit is configured to issue a notification of a mark abnormality if a result of determining whether or not the imprint process is executable is that the imprint process is determined not to be executable.

9. The imprint apparatus according to claim 1,
wherein the control unit is configured to cause the observation unit to observe the selected mold-side mark after a positional deviation amount of the mold held by a mold holding unit is measured.

10. An imprint method that executes an imprint process of forming a pattern to an imprint material on a substrate using a mold, the imprint method comprising:
selecting, from among a plurality of mold-side marks formed on the mold, the mold-side marks to be used in the imprint process, observing the selected mold-side marks before the imprint process is executed, and determining whether or not the imprint process is executable, based on an observation result.

11. An article manufacturing method comprising:
by using an imprint method that executes an imprint process of forming a pattern to an imprint material on a substrate using a mold, selecting, from among a plurality of mold-side marks formed on the mold, the mold-side marks to be used in the imprint process, observing the selected mold-side marks before the imprint process is executed, and determining whether or not the imprint process is executable, based on an observation result;
forming a pattern on the substrate by using the imprint method,
processing the substrate with the pattern formed in the forming; and
manufacturing an article from the substrate processed in the processing.
